(19) United States
(12) Patent Application Publication
(10) Pub. No.: US 2025/0221289 A1
(43) Pub. Date: Jul. 3, 2025

(54) METHOD FOR MANUFACTURING DISPLAY DEVICE

(71) Applicant: Samsung Display Co., LTD., Yongin-si (KR)

(72) Inventors: Rang Kyun MOK, Yongin-si (KR); Tae Ho LEE, Yongin-si (KR)

(21) Appl. No.: 18/770,218

(22) Filed: Jul. 11, 2024

(30) Foreign Application Priority Data
Dec. 27, 2023 (KR) 10-2023-0192071

(51) Int. Cl. H10K 71/60; H10K 59/80

(52) U.S. Cl. CPC H10K 71/611; H10K 59/8792

(57) ABSTRACT

In a method for manufacturing a display device, the method includes: providing a first electrode on a display module, a light transmitting film on the first electrode, and a light blocking material layer on the light transmitting film; forming a plurality of light blocking films by removing a residual film of the light blocking material layer on an upper surface of the light transmitting film; and forming a second electrode on the light transmitting film and the plurality of light blocking films, wherein the residual film is removed using an air knife.

### CROSS-REFERENCE TO RELATED APPLICATION

The present application claims priority to and the benefit of Korean Patent Application No. 10-2023-0192071, filed on Dec. 27, 2023, in the Korean Intellectual Property Office, the entire disclosure of which is incorporated herein by reference.

### BACKGROUND

### 1. Field

Aspects of some embodiments of the present disclosure relate to a method for manufacturing a display device.

### 2. Description of the Related Art

As an information society develops, consumer demand for display devices for displaying images is increasing in various forms. The display devices may be displays such as liquid crystal displays (LCDs), field emission displays (FEDs), or light emitting displays (LEDs). The light emitting display may include an organic light emitting display device including an organic light emitting diode element as a light emitting element, or an inorganic light emitting display device including an inorganic light emitting diode element as a light emitting element.

In the case of a vehicle display device, when images are displayed on the vehicle display device located in front of a driver or passenger is reflected on a windshield at night, it may interfere with the driver's driving, and therefore, it may be desirable to control a viewing angle of the images displayed on the vehicle display device. In addition, in order to protect privacy, it may be desirable to control the viewing angle of the images displayed on the vehicle display device so that the images displayed on the vehicle display device located in front of the driver is not provided to the passenger.

The above information disclosed in this Background section is only for enhancement of understanding of the background and therefore the information discussed in this Background section does not necessarily constitute prior art.

### SUMMARY

Aspects of some embodiments of the present disclosure provide a method for manufacturing a display device that may remove a residual film on a light transmitting film.

However, aspects of embodiments according to the present disclosure are not restricted to those set forth herein. The above and other aspects of embodiments of the present disclosure will become more apparent to one of ordinary skill in the art to which the present disclosure pertains by referencing the detailed description of embodiments according to the present disclosure given below.

According to some embodiments of the present disclosure, there is provided a method for manufacturing a display device, the method including, providing a first electrode on a display module, a light transmitting film on the first electrode, and a light blocking material layer on the light transmitting film, forming a plurality of light blocking films by removing a residual film of the light blocking material layer positioned on an upper surface of the light transmitting film, and forming a second electrode on the light transmitting film and the plurality of light blocking films, wherein the residual film is removed using an air knife.

According to some embodiments, the light transmitting film includes a plurality of receiving portions, and the plurality of light blocking films are each within the plurality of receiving portions.

According to some embodiments, the air knife sprays an air stream onto the light blocking material layer.

According to some embodiments, the plurality of receiving portions include a first receiving portion and a second receiving portion spaced apart from each other, the air knife includes an air nozzle through which the air stream is sprayed, and when an end of the air nozzle is positioned on a right end of the first receiving portion, the air stream is sprayed toward a right end of the second receiving portion.

According to some embodiments, a first angle, which is an angle formed between an extension direction of the upper surface of the light transmitting film and a spraying direction of the air stream, is θ1, a first distance, which is a distance between the plurality of light blocking films, is D1, and a first width, which is a width of the plurality of light blocking films, is W1, a first height, which is a distance between the upper surface of the light transmitting film and the air nozzle, is H1, and θ1=tan−1{H1/(W1+D1)} is satisfied.

According to some embodiments, the first angle is 5 degrees to 30 degrees.

According to some embodiments, the first height is 10 μm to 15 μm.

According to some embodiments, an air volume of the air stream is 100 CFM or more.

According to some embodiments, the light blocking film includes electrophoretic particles.

According to some embodiments, the electrophoretic particles have a charge.

According to some embodiments, the light blocking film includes a charge control agent.

According to some embodiments, the first electrode and the second electrode include a transparent conductive material.

According to some embodiments of the present disclosure, there is provided a method for manufacturing a display device, the method including, providing a first electrode on a display module, a light transmitting film on the first electrode, and an object including a light blocking material layer on the light transmitting film, forming a plurality of light blocking films by removing a residual film of the light blocking material layer positioned on an upper surface of the light transmitting film, and forming a second electrode on the light transmitting film and the plurality of light blocking films, wherein the light transmitting film includes a plurality of receiving portions extending in a first direction and arranged in a second direction different from the first direction, and the residual film is removed using an air knife.

According to some embodiments, at least one of the air knife or the object moves in the second direction.

According to some embodiments, the plurality of receiving portions include a first receiving portion and a second receiving portion spaced apart from each other, the air knife includes an air nozzle through which an air stream is sprayed, and when an end of the air nozzle is positioned on a right end of the first receiving portion, the air stream is sprayed toward a right end of the second receiving portion.

According to some embodiments, a first angle, which is an angle formed between an extension direction of the upper surface of the light transmitting film and a spraying direction of the air stream, is θ1, a first distance, which is a distance between the plurality of light blocking films, is D1, and a first width, which is a width of the plurality of light blocking films, is W1, a first height, which is a distance between the upper surface of the light transmitting film and the air nozzle, is H1, and θ1=tan−1{H1/(W1+D1)} is satisfied.

According to some embodiments, at least one of the air knife or the object moves in the first direction.

According to some embodiments, the air knife includes an air nozzle through which an air stream is sprayed.

According to some embodiments, the air nozzle extends in the second direction, and overlaps the plurality of receiving portions.

According to some embodiments, the air nozzle includes a plurality of air nozzles, and the plurality of air nozzles each overlap portions of the light transmitting film other than the plurality of receiving portions.

In a method for manufacturing the display device according to some embodiments of the present disclosure, the residual film on the light transmitting film may be removed.

However, the characteristics of embodiments are not restricted to those set forth herein. The above and other effects of the embodiments will become more apparent to one of ordinary skill in the art to which the embodiments pertain by referencing the claims.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating a display device according to some embodiments;

FIG. 3 is a schematic cross-sectional view of the display device taken along the line X1-X1′ of FIG. 2;

FIG. 4 is a schematic view when the display device according to some embodiments is applied to a vehicle;

FIG. 5 is a cross-sectional view illustrating an example of a display module according to some embodiments;

FIG. 6 is a cross-sectional view illustrating a viewing angle limited mode state of a display panel according to some embodiments;

FIG. 7 is a cross-sectional view showing a wide viewing angle mode state of a display panel according to some embodiments;

FIG. 8 is a flowchart illustrating a method for manufacturing a display device according to some embodiments;

FIG. 9 is a perspective view illustrating aspects of the operation S100 of FIG. 8;

FIGS. 10 and 11 are perspective views illustrating aspects of the operation S200 of FIG. 8;

FIG. 12 is a perspective view illustrating aspects of the operation S300 of FIG. 8;

FIG. 13 is a perspective view illustrating aspects of the operation S400 of FIG. 8;

FIG. 14 is a cross-sectional view taken along the line X2-X2′ of FIG. 13;

FIG. 15 is an enlarged view of the area A of FIG. 14;

FIG. 16 is a perspective view illustrating aspects of the operation S500 of FIG. 8;

FIG. 17 is a photograph illustrating an upper surface of a light transmitting film and a light blocking film according to a comparative example;

FIG. 18 is a photograph illustrating an upper surface of a light transmitting film and a light blocking film according to some embodiments;

FIG. 19 is a perspective view illustrating operation S400_1 showing further details of the operation S400 of FIG. 8;

FIG. 20 is a perspective view illustrating operation S400_2 showing further details of the operation S400 of FIG. 8; and

FIG. 21 is a cross-sectional view taken along the line X3-X3′ of FIG. 20.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

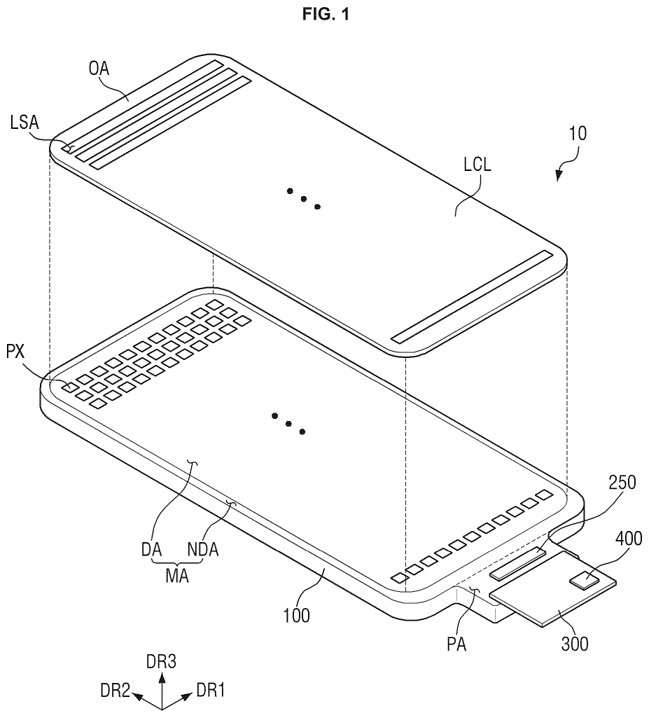

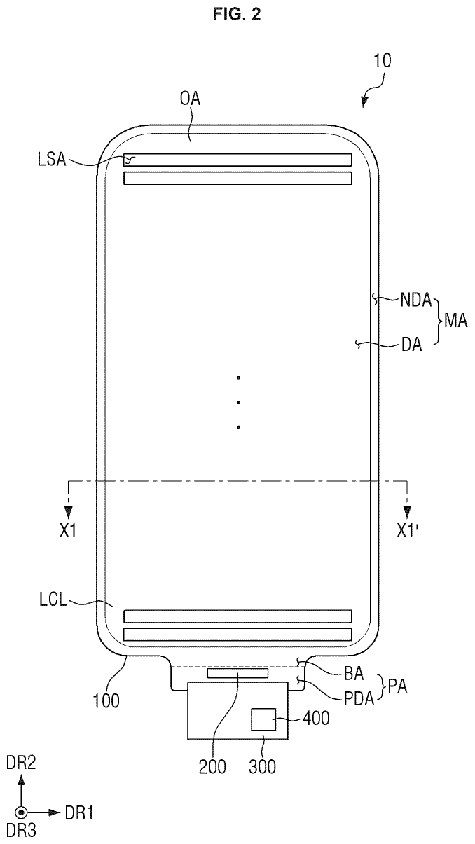

FIG. 1 is a perspective view illustrating a display device according to some embodiments. FIG. 2 is a plan view illustrating a display device according to some embodiments.

Referring to FIGS. 1 and 2, a display device 10 is a device that displays a moving image or a still image, and may be used as a display screen of each of various products such as a vehicle, a television, a laptop computer, a monitor, a billboard, and Internet of Things (IOT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

In some embodiments, when the display device 10 is used as a display screen for a vehicle, the display device 10 may be a vehicle display. The vehicle display may provide users with various service information such as convenience functions, media information, etc., as well as information about vehicle operation information and status information. When the display device 10 includes an input device such as a touch panel, the user may manipulate various functions such as a driving mode of the vehicle and convenience functions through the display device 10.

The display device 10 may be any one of an organic light emitting display device, a liquid crystal display device, a plasma display device, a field emission display device, an electrophoretic display device, an electrowetting display device, a quantum dot light emitting display device, and a micro LED display device. Hereinafter, it is mainly described that the display device 10 is the organic light emitting display device, but the present disclosure is not limited thereto.

The display device 10 according to some embodiments may include a display panel 100, a display driving circuit 250, a circuit board 300, and a touch driving circuit 400.

The display panel 100 may include a plurality of pixels PX arranged in a first direction DR1 and a second direction DR2. Each of the pixels PX may have a planar shape such as a rectangle, a square, or a rhombus. For example, as illustrated in the drawing, each of the pixels PX may have a planar shape such as a square. However, each of the pixels PX is not limited thereto, and may have various shapes such as a polygon, a circle, and an ellipse in plan view.

In the illustrated drawings, the first direction DR1 and the second direction DR2 are each horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. In the present specification, a direction indicated by the first to third directions DR1, DR2, and DR3 in the drawing may be referred to as one side, and an opposite direction may be referred to as the other side, and unless otherwise specified, may include both sides.

The display panel 100 may include a main area MA and a protruding area PA protruding from one side of the main area MA.

The main area MA may be formed in a rectangular plane having short sides in the first direction DR1 and long sides in the second direction DR2 intersecting the first direction DR1. A corner where the short side in the first direction DR1 and the long side in the second direction DR2 meet may be rounded to have a curvature (e.g., a set or predetermined curvature) or may be formed at a right angle. The planar shape of the display device 10 is not limited to a quadrangular shape, and may be formed in other polygonal, circular, or oval shapes. The main area MA may be formed to be flat, but is not limited thereto, and may include curved portions formed at left and right ends. In this case, the curved portion may have a constant curvature or a changing curvature.

The main area MA may include a display area DA in which pixels are formed to display an image, and a non-display area NDA which is a peripheral area (e.g., in a periphery or outside a footprint) of the display area DA.

In the display area DA, not only pixels but also scan lines, data lines, and power lines connected to the pixels may be located. When the main area MA includes the curved portion, the display area DA may be located on the curved portion. In this case, the images displayed at the display panel 100 may be viewed even on the curved portion.

The non-display area NDA may be defined as an area from the outside of the display area DA to an edge of the display panel 100. A scan driver for applying scan signals to the scan lines and link lines connecting the data lines and the display driving circuit 250 may be located in the non-display area NDA.

The protruding area PA may protrude from one side of the main area MA. For example, the protruding area PA may protrude from a lower side of the main area MA as illustrated in FIG. 2. A length of the protruding area PA in the first direction DR1 may be smaller than a length of the main area MA in the first direction DR1.

The protruding area PA may include a bending area BA and a pad area PDA. In this case, the pad area PDA may be located on one side of the bending area BA, and the main area MA may be located on the other side of the bending area BA. For example, the pad area PDA may be located on a lower side of the bending area BA, and the main area MA may be located on an upper side of the bending area BA.

The display panel 100 may be flexibly formed to be curved, bent, folded, or rolled. Therefore, the display panel 100 may be bent in a thickness direction, that is, in a third direction DR3, in the bending area BA. In this case, before the display panel 100 is bent, one surface of the pad area PDA of the display panel 100 faces upward, but after the display panel 100 is bent, one surface of the pad area PDA of the display panel 100 faces downward. As a result, because the pad area PDA is located on a lower side of the main area MA, the pad area PDA may overlap the main area MA.

Pads electrically connected to the display driving circuit 250 and the circuit board 300 may be located in the pad area PDA of the display panel 100.

The display driving circuit 250 outputs signals and voltages for driving the display panel 100. For example, the display driving circuit 250 may supply data voltages to the data lines. In addition, the display driving circuit 250 may supply power voltage to the power line and scan control signals to a scan driver. The display driving circuit 250 may be formed as an integrated circuit (IC) and be attached onto the display panel 100 in the pad area PDA using a chip on glass (COG) method, a chip on plastic (COP) method, or an ultrasonic bonding method, but is not limited thereto. For example, the display driving circuit 250 may be mounted on the circuit board 300.

The pads may include display pads electrically connected to the display driving circuit 250 and touch pads electrically connected to the touch lines.

The circuit board 300 may be attached onto the pads using an anisotropic conductive film. Accordingly, lead lines of the circuit board 300 may be electrically connected to the pads. The circuit board 300 may be a flexible printed circuit board, a printed circuit board, or a flexible film such as a chip on film.

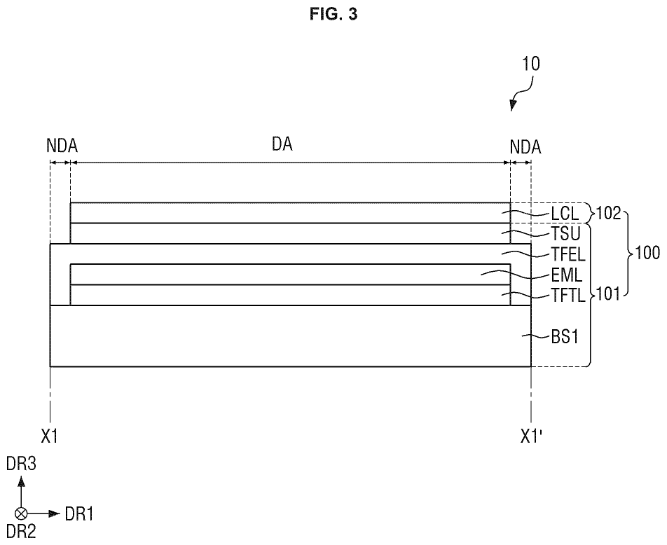

The touch driving circuit 400 may be connected to touch electrodes of a touch sensor layer TSU (see FIG. 3) of the display panel 100. The touch driving circuit 400 applies driving signals to the touch electrodes of the touch sensor layer TSU (see FIG. 3) and measures capacitance values of the touch electrodes. The driving signal may be a signal having a plurality of driving pulses. The touch driving circuit 400 may not only determine whether a touch is input but also calculate touch coordinates where a touch is input, based on the capacitance values.

The touch driving circuit 400 may be located on the circuit board 300. The touch driving circuit 400 may be formed as an integrated circuit (IC) and mounted on the circuit board 300.

In the display device 10 according to some embodiments, the display panel 100 may further include a light control layer LCL.

The light control layer LCL may be directly located in the main area MA of the display panel 100. For example, the light control layer LCL may be embedded in the display panel 100 and directly located on the main area MA of the display panel 100. As the light control layer LCL is embedded in the display panel 100, the thickness and manufacturing cost of the display device 10 may be relatively reduced compared to when a separate light control film is attached.

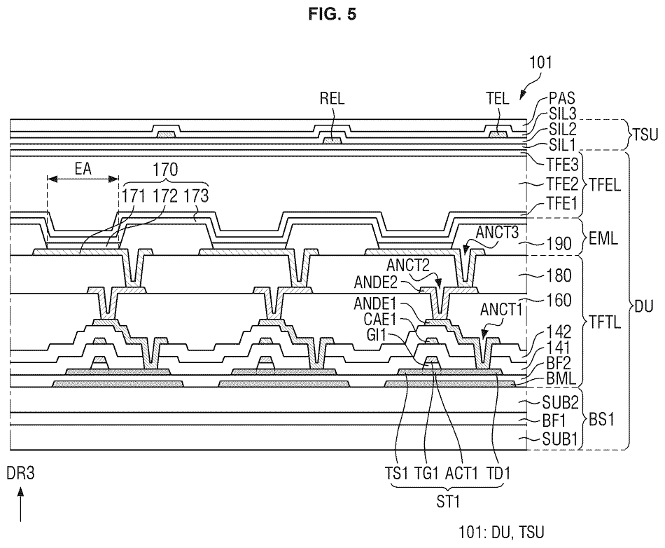

In some embodiments, the light control layer LCL may be located on the display area DA of the main area MA. The light control layer LCL may control a viewing angle of light emitted from a light emitting layer 172 (see FIG. 5) of the display panel 100.

However, the present disclosure is not limited thereto, and a size of the light control layer LCL in plan view may be greater than a size of the display area DA. In this case, the light control layer LCL may overlap both the display area DA and the non-display area NDA.

In some embodiments, the light control layer LCL may include a transmissive area OA and a non-transmissive area LSA.

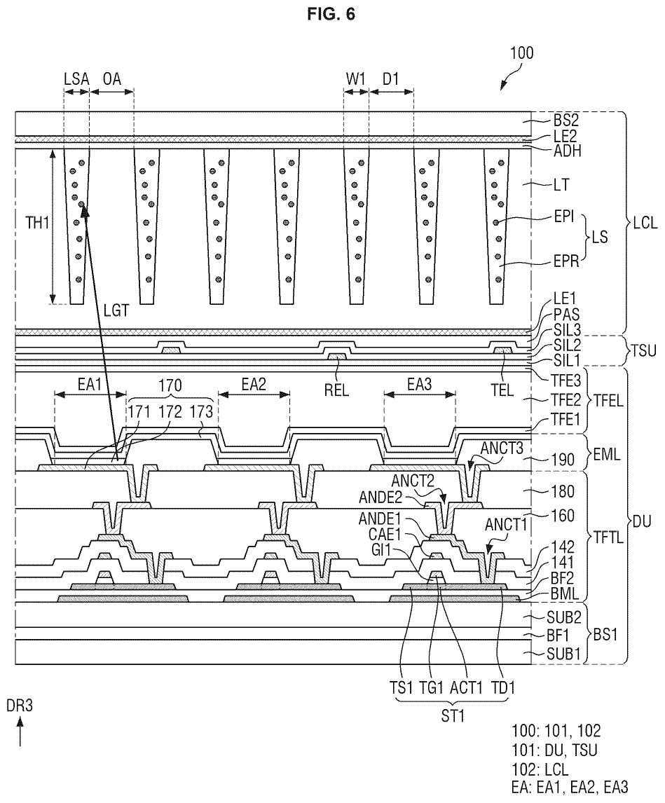

The transmissive area OA may be an area in which the light blocking film LS (see FIG. 6) is not located. The transmissive area OA, which is an area that transmits light, may extend along the third direction DR3.

The transmissive area OA may have a quadrangular shape in plan view as illustrated in FIGS. 1 and 2, but is not limited thereto. Each of the transmissive areas OA may have a circular, oval, or polygonal shape in plan view. In some embodiments, the shape of the transmissive area OA may substantially correspond to the shape of the display panel 100.

The non-transmissive areas LSA may be remaining areas of the light control layer LCL excluding the transmissive area OA. The non-transmissive areas LSA may be areas in which the light blocking film LS (see FIG. 6) is located.

In some embodiments, the non-transmissive areas LSA may extend in the first direction DR1 or the second direction DR2. As an example, as illustrated in FIG. 1, the non-transmissive area LSA may extend in the first direction DR1 and be arranged along the second direction DR2. As another example, the non-transmissive area LSA may extend in the second direction DR2 and be arranged along the first direction DR1. As still another example, some of the non-transmissive areas LSA may extend in the first direction DR1 and be arranged along the second direction DR2, and the remaining portion of the non-transmissive areas LSA may extend in the second direction DR2 and be arranged along the first direction DR1.

According to some embodiments, as illustrated in FIG. 1, when the non-transmissive areas LSA are arranged along the second direction DR2, the viewing angle may be controlled in the second direction DR2. According to some embodiments, when the non-transmissive areas LSA are arranged along the first direction DR1, the viewing angle may be controlled in the first direction DR1. In the display device 10 according to some embodiments, the arrangement and shape of the transmissive area OA and the non-transmissive area LSA may be variously changed depending on the required control direction of the viewing angle.

Meanwhile, it is illustrated in the drawings that the transmissive area OA is arranged to surround the non-transmissive areas LSA, but the present disclosure is not limited thereto. In some embodiments, the transmissive area OA may include a plurality of transmissive areas OA, and the plurality of transmissive areas OA extend in the same direction as the non-transmissive areas LSA, so that the plurality of transmissive areas OA and non-transmissive areas LSA may be arranged to alternate with each other. For example, as illustrated in FIG. 1, when the non-transmissive areas LSA extend in the first direction DR1, the transmissive areas OA may extend in the first direction DR1 and may be arranged to alternate with the non-transmissive areas LSA in the second direction DR2.

The light control layer LCL may include a light blocking film LS (see FIG. 6) that blocks light emitted from a light emitting layer 172 (see FIG. 5) of the display panel 100 and a light transmitting film LT (see FIG. 6) that transmits the light. The detailed structure of the light control layer LCL will be described later with reference to FIG. 6 and the like.

FIG. 3 is a schematic cross-sectional view of the display device taken along line X1-X1′ of FIG. 2.

Referring to FIG. 3, the display device 10 may include a display panel 100 in which the light control layer LCL is embedded. The display panel 100 may include a display module 101 and a light control module 102.

The display module 101 may include a first base substrate BS1, a thin film transistor layer TFTL, a light emitting element layer EML, a thin film encapsulation layer TFEL, and a touch sensor layer TSU.

The first base substrate BS1 may include a substrate. The substrate may be made of an insulating material such as glass, quartz, or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate may also include a metal material.

The substrate may be a rigid substrate or may be a flexible substrate that may be bent, folded, and rolled. When the substrate is the flexible substrate, the substrate may be formed of polyimide PI, but is not limited thereto.

The thin film transistor layer TFTL may be located on the first base substrate BS1. In the thin film transistor layer TFTL, scan lines, data lines, power lines, scan control lines, and routing lines connecting the pads and the data lines as well as thin film transistors of each of the pixels may be formed. Each of the thin film transistors may include a gate electrode, a semiconductor layer, a source electrode, and a drain electrode.

The thin film transistor layer TFTL may be located in the display area DA and the non-display area NDA. Specifically, the thin film transistors of each of the pixels, the scan lines, the data lines, and the power lines of the thin film transistor layer TFTL may be located in the display area DA. The scan control lines and link lines of the thin film transistor layer TFTL may be located in the non-display area NDA.

The light emitting element layer EML may be located on the thin film transistor layer TFTL. The light emitting element layer EML may include pixels including a first electrode, a light emitting layer, and a second electrode, and a pixel defining film defining the pixels. The light emitting layer may be an organic light emitting layer including an organic material. In this case, the light emitting layer may include a hole transporting layer, an organic light emitting layer, and an electron transporting layer. When a voltage (e.g., a set or predetermined voltage) is applied to the first electrode and a cathode voltage is applied to the second electrode through the thin film transistor of the thin film transistor layer TFTL, holes and electrons move to the organic light emitting layer through the hole transporting layer and the electron transporting layer, respectively, and are combined with each other in the organic light emitting layer to emit light. The pixels of the light emitting element layer EML may be located in the display area DA.

The thin film encapsulation layer TFEL may be located on the light emitting element layer EML. The thin film encapsulation layer TFEL may serve to prevent oxygen or moisture from permeating into the light emitting element layer EML. To this end, the thin film encapsulation layer TFEL may include at least one inorganic film. The inorganic film may be a silicon nitride layer, a silicon oxynitride layer, a silicon oxide layer, a titanium oxide layer, or an aluminum oxide layer, but is not limited thereto. In addition, the thin film encapsulation layer TFEL may serve to protect the light emitting element layer EML from foreign substances such as dust. To this end, the thin film encapsulation layer TFEL may include at least one organic film. The organic film may be made of an acrylic resin, an epoxy resin, a phenolic resin, a polyamide resin, or a polyimide resin, but is not limited thereto.

The thin film encapsulation layer TFEL may be located in both the display area DA and the non-display area NDA. Specifically, the thin film encapsulation layer TFEL may be arranged to cover the light emitting element layer EML of the display area DA and the non-display area NDA, and cover the thin film transistor layer TFTL of the non-display area NDA.

The touch sensor layer TSU may be located on the thin film encapsulation layer TFEL. As the touch sensor layer TSU is directly located on the thin film encapsulation layer TFEL, the thickness of the display device 10 may be relatively reduced as compared to when a separate touch panel including the touch sensor layer TSU is attached onto the thin film encapsulation layer TFEL.

The touch sensor layer TSU may include touch electrodes for sensing a user's touch in a capacitance method, and touch lines connecting the pads and the touch electrodes. For example, the touch sensor layer TSU may sense a user's touch in a self-capacitance method or a mutual capacitance method.

The touch electrodes of the touch sensor layer TSU may be located in a touch sensor area overlapping the display area DA. The touch lines of the touch sensor layer TSU may be located in a touch peripheral area overlapping the non-display area NDA.

The light control module 102 may be located on the display module 101. The light control module 102 may include a light control layer LCL.

The light control layer LCL may be located on the display module 101. The light control layer LCL may be arranged to overlap display area DA. The light control layer LCL may serve to absorb or block light that travels beyond a certain angle with respect to the third direction DR3 among the light emitted from the light emitting element layer EML. That is, the light control layer LCL may control the viewing angle.

According to some embodiments, the display device 10 may further include a cover window. The cover window may be additionally located on the light control layer LCL. In this case, the light control layer LCL and the cover window may be attached by a transparent adhesive member such as an optically clear adhesive (OCA) film.

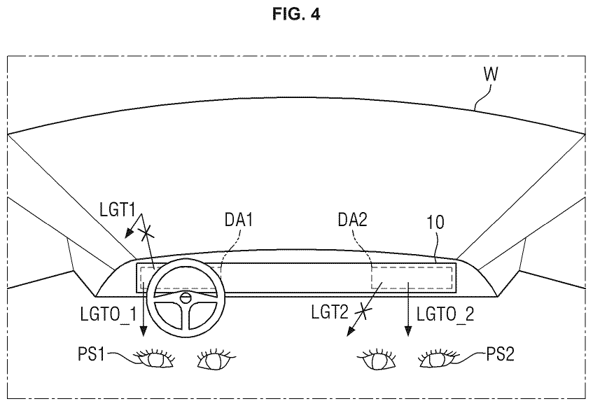

FIG. 4 is a schematic view when the display device according to some embodiments is applied to a vehicle.

Referring to FIG. 4, the display device 10 according to some embodiments may be, for example, a display device applied to a vehicle. The vehicle may include a body forming an exterior of the vehicle and an interior space defined by the body. The body may include a windshield W that protects a driver PS1 and a passenger PS2 from the outside and provides visibility to the driver PS1. As illustrated in the drawing, the display device 10 may be provided in the interior space.

In some embodiments, the display device 10 may be located on a dashboard provided in the interior space. As an example, as illustrated in FIG. 4, the display device 10 may extend from the dashboard positioned in front of a driver's seat to the dashboard positioned in front of a passenger seat. For example, the display device 10 may be an integrated display connected from the dashboard positioned in front of the driver's seat to the dashboard positioned in front of the passenger seat.

The display device 10 may include a first display area DA1 positioned in front of the driver's seat and a second display area DA2 positioned in front of the passenger seat. The first display area DA1 may be located on the dashboard in front of the driver's seat and provide speed information, etc. to the driver PS1, and the second display area DA2 may be located on the dashboard in front of the passenger seat and provide entertainment information, etc. to the passenger PS2. According to some embodiments, the display device 10 may further include a third display area between the first display area DA1 and the second display area DA2.

As another example, the display device 10 may be located on the dashboard in front of the driver's seat and the dashboard in front of the passenger seat, respectively. For example, a first display device may be located on the dashboard in front of the driver's seat, and a second display device may be located on the dashboard in front of the passenger seat.

The driver PS1 may recognize (or visually recognize) a display screen of the display device 10 through light LGT0_1 emitted from the display device 10 towards the driver PS1. However, some light LGT1 among the light emitted from the display device 10 in front of the driver's seat may be reflected on the surrounding windshield W and provided to the driver PS1. In this case, the image displayed on the windshield W may interfere with the driving of the driver PS1. On the other hand, in the case of the display device 10 according to some embodiments, it is possible to prevent in advance that some light LGT1 of the light emitted from the display device 10 in front of the driver's seat is reflected on the surrounding windshield W and provided to the driver PS1 by adjusting a viewing angle, especially a vertical viewing angle, with respect to a front direction (direction facing the driver PS1) of the light emitted from the display device 10.

The passenger PS2 may recognize (or visually recognize) a display screen of the display device 10 through light LGT0_2 emitted from the display device 10 towards the passenger PS2. However, some light LGT2 of the light emitted from the display device 10 in front of the passenger seat may be provided toward the passenger PS1. In this case, when the vehicle is driving, the viewing of the driver PS1 may be restricted for reasons such as safety. In the case of the display device 10 according to some embodiments, it is possible to prevent some light LGT2 of the light emitted from the display device 10 in front of the passenger seat from being provided to the driver by adjusting the viewing angle, especially the left and right viewing angles, with respect to the front direction (direction facing the passenger PS2) of the light emitted from the display device 10. On the other hand, when the vehicle is stopped, the image of the second display area DA2 may be provided to the driver PS1.

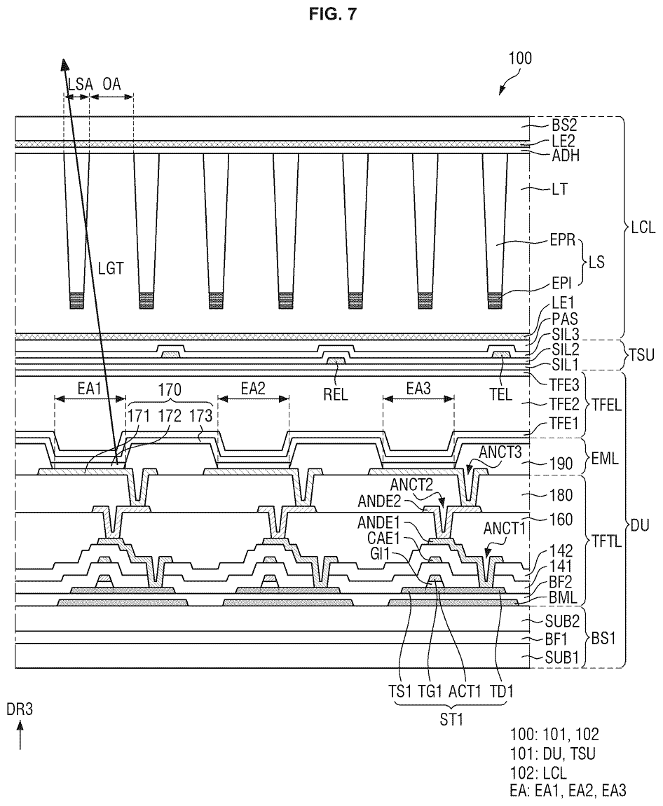

As such, the display device 10 may be a viewing angle-adjustable switching display capable of switching between a viewing angle limited mode that limits the viewing angle and a wide viewing angle mode that does not limit the viewing angle. A method of switching between the viewing angle limited mode and the wide viewing angle mode will be described later with reference to FIGS. 6 and 7.

It is illustrated in the drawing that the display device 10 in front of the driver's seat adjusts the vertical viewing angle, and the display device 10 in front of the passenger seat adjusts the left and right viewing angle, but the present disclosure is not limited thereto. As an example, the display device 10 in front of the driver's seat may also adjust the right and left viewing angle, and the display device 10 in front of the passenger seat may also adjust the vertical viewing angle. As another example, the display device 10 in front of the driver's seat and the display device 10 in front of the passenger seat may also adjust both the vertical viewing angle and the left and right viewing angle, respectively.

The viewing angle may be adjusted through the light control layer LCL. The viewing angle may be limited to an angle range (e.g., a set or predetermined angle range) through the light control layer LCL. As an example, when an imaginary line facing the driver PS1 or passenger PS2 in the front direction and extending in a direction perpendicular to the display surface of the display device 10 is taken as a normal line, the viewing angle may be an angle within 35° from the normal line. In some embodiments, the angle within 35° from the normal line may be defined as an effective viewing angle, but is not limited thereto.

FIG. 5 is a cross-sectional view illustrating an example of a display module according to some embodiments.

Referring to FIG. 5, the display module 101 may include a display layer DU and a touch sensor layer TSU. The display layer DU may include a first base substrate BS1, a thin film transistor layer TFTL, a light emitting element layer EML, and a thin film encapsulation layer TFEL.

The first base substrate BS1 may include a first substrate SUB1, a first buffer film BF1 located on the first substrate SUB1, and a second substrate SUB2 located on the first buffer film BF1.

The first substrate SUB1 and the second substrate SUB2 may be made of an insulating material such as glass, quartz, or polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate may also include a metal material.

The first substrate SUB1 and the second substrate SUB2 may be rigid substrates or flexible substrates that may be bent, folded, and rolled. When the substrate is the flexible substrate, the substrate may be formed of polyimide PI, but is not limited thereto.

The first buffer film BF1 is a film for protecting a first thin film transistor ST1 and a light emitting layer 172 from moisture permeating through the first and second substrates SUB1 and SUB2, which are vulnerable to moisture permeation. The first buffer film BF1 may be formed of a plurality of inorganic films alternately stacked. For example, the first buffer film BF1 may be formed of a multi-film in which one or more inorganic films of a silicon nitride layer, a silicon oxynitride layer, a silicon oxide layer, a titanium oxide layer, and an aluminum oxide layer are alternately stacked.

The thin film transistor layer TFTL may include a lower metal layer BML, a second buffer film BF2, a first thin film transistor ST1, a first gate insulating film GI1, a first interlayer insulating film 141, a first capacitor electrode CAE1, a second interlayer insulating film 142, a first anode connection electrode ANDE1, a first organic film 160, a second anode connection electrode ANDE2, and a second organic film 180.

The lower metal layer BML may be located on the second substrate SUB2. The lower metal layer BML may be arranged to overlap a first active layer ACT1 of the first thin film transistor ST1 in the third direction DR3 to prevent leakage current from occurring when light is incident on the first active layer ACT1 of the first thin film transistor ST1. The lower metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. The lower metal layer BML may be omitted.

The second buffer film BF2 may be located on the lower metal layer BML. The second buffer film BF2 is a film for protecting the first thin film transistor ST1 and the light emitting layer 172 from moisture permeating through the first and second substrates SUB1 and SUB2, which are vulnerable to moisture permeation. The second buffer film BF2 may be formed of a plurality of inorganic films alternately stacked. For example, the second buffer film BF2 may be formed of a multi-film in which one or more inorganic films of a silicon nitride layer, a silicon oxynitride layer, a silicon oxide layer, a titanium oxide layer, and an aluminum oxide layer are alternately stacked.

The first active layer ACT1 of the first thin film transistor ST1 may be located on the second buffer film BF2. The first active layer ACT1 of the first thin film transistor ST1 includes polycrystalline silicon, single crystal silicon, low-temperature polycrystalline silicon, amorphous silicon, or an oxide semiconductor. The first active layer ACT1 of the first thin film transistor ST1 exposed and not covered by the first gate insulating film GI1 may be doped with impurities or ions to have conductivity. Therefore, a first source electrode TS1 and a first drain electrode TD1 of the first active layer ACT1 of the first thin film transistor ST1 may be formed.

The first gate insulating film GI1 may be located on the first active layer ACT1 of the first thin film transistor ST1. It is illustrated in FIG. 6 that the first gate insulating film GI1 is located between a first gate electrode TG1 and the first active layer ACT1 of the first thin film transistor ST1, but the present disclosure is not limited thereto. The first gate insulating film GI1 may also be located between the first interlayer insulating film 141 and the first active layer ACT1 and between the first interlayer insulating film 141 and the second buffer film BF2. The first gate insulating film GI1 may be formed as an inorganic film, for example, a silicon nitride layer, a silicon oxynitride layer, a silicon oxide layer, a titanium oxide layer, or an aluminum oxide layer.

The first gate electrode TG1 of the first thin film transistor ST1 may be located on the first gate insulating film GI1. The first gate electrode TG1 of the first thin film transistor ST1 may overlap the first active layer ACT1 in the third direction DR3. The first gate electrode TG1 of the first thin film transistor ST1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first interlayer insulating film 141 may be located on the first gate electrode TG1 of the first thin film transistor ST1. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

The first capacitor electrode CAE1 may be located on the first interlayer insulating film 141. The first capacitor electrode CAE1 may overlap the first gate electrode TG1 of the first thin film transistor ST1 in a third direction (Z-axis direction). Because the first interlayer insulating film 141 has a dielectric constant (e.g., a set or predetermined dielectric constant), a capacitor may be formed by the first capacitor electrode CAE1, the first gate electrode TG1, and the first interlayer insulating film 141 located between the first capacitor electrode CAE1 and the first gate electrode TG1. The first capacitor electrode CAE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second interlayer insulating film 142 may be located on the first capacitor electrode CAE1. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first anode connection electrode ANDE1 may be located on the second interlayer insulating film 142. The first anode connection electrode ANDE1 may be connected to the first drain electrode TD1 of the first thin film transistor ST1 through a first anode contact hole ANCT1 penetrating through the first interlayer insulating film 141 and the second interlayer insulating film 142 to expose the first drain electrode TD1 of the first thin film transistor ST1. The first anode connection electrode ANDE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first organic film 160 for planarization may be located on the first pixel connection electrode ANDE1. The first organic film 160 may be formed of an organic film made of an acryl resin, an epoxy resin, a phenolic resin, a polyamide resin, a polyimide resin, or the like.

The second anode connection electrode ANDE2 may be located on the first organic film 160. The second anode connection electrode ANDE2 may be connected to the first anode connection electrode ANDE1 through a second anode contact hole ANCT2 penetrating through the first organic film 160 to expose the first anode connection electrode ANDE1. The second anode connection electrode ANDE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second organic film 180 may be located on the second anode connection electrode ANDE2. The second organic film 180 may be formed of an organic film made of an acryl resin, an epoxy resin, a phenolic resin, a polyamide resin, a polyimide resin, or the like.

It is illustrated in FIG. 5 that the first thin film transistor ST1 is formed in a top gate type in which the first gate electrode TG1 is positioned above the first active layer ACT1, but the present disclosure is not limited thereto. The first thin film transistor ST1 may be formed in a bottom gate type in which the first gate electrode TG1 is positioned below the first active layer ACT1 or a double gate type in which the first gate electrode TG1 is positioned both above and below the first active layer ACT1.

The light emitting element layer EML may be located on the second organic film 180. The light emitting element layer EML may include light emitting elements 170 and a bank 190. Each of the light emitting elements 170 may include a first light emitting electrode 171, a light emitting layer 172, and a second light emitting electrode 173.

The first light emitting electrode 171 may be formed on the second organic film 180. The first light emitting electrode 171 may be connected to the second anode connection electrode ANDE2 through a third anode contact hole ANCT3 penetrating through the second organic film 180 to expose the second anode connection electrode ANDE2.

The first light emitting electrode 171 may be formed on the second organic film 180. The first light emitting electrode 171 may be connected to the second anode connection electrode ANDE2 through a third anode contact hole ANCT3 penetrating through the second organic film 180 to expose the second anode connection electrode ANDE2.

In a top emission structure in which light is emitted toward the second light emitting electrode 173 based on the light emitting layer 172, the first light emitting electrode 171 may be formed of a metal material having high reflectance, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the first light emitting electrode 171 on the second organic film 180 to define a light emitting area EA. The bank 190 may include an opening that exposes at least a portion of an upper surface of the first light emitting electrode 171. The bank 190 may be formed to cover an edge of the first light emitting electrode 171. The bank 190 may be formed of an organic film such as an acrylic resin, an epoxy resin, a phenolic resin, a polyamide resin, or a polyimide resin.

The light emitting area EA refers to an area in which the first light emitting electrode 171, the light emitting layer 172, and the second light emitting electrode 173 are sequentially stacked and holes from the first light emitting electrode 171 and electrons from the second light emitting electrode 173 are combined with each other in the light emitting layer 172 to emit light. The light emitting area EA may be defined by the opening of the bank 190.

The light emitting layer 172 is formed on the first light emitting electrode 171 and the bank 190. The light emitting layer 172 may be located within the opening of the bank 190, but is not limited thereto. The light emitting layer 172 may include an organic material to emit light of a color (e.g., a set or predetermined color). For example, the light emitting layer 172 may include a hole transporting layer, an organic material layer, and an electron transporting layer.

The second light emitting electrode 173 may be located on the light emitting layer 172. The second light emitting electrode 173 may be formed to cover the light emitting layer 172. The second light emitting electrode 173 may be a common layer commonly formed in all the light emitting areas EA. According to some embodiments, a capping layer may be formed on the second light emitting electrode 173.

In the top emission structure, the second light emitting electrode 173 may be formed of transparent conductive oxide (TCO) such as indium tin oxide (ITO) or indium zinc oxide (IZO) capable of transmitting light, or a semi-transmissive conductive material such as magnesium (Mg), silver (Ag), or an alloy of magnesium (Mg) and silver (Ag). When the second light emitting electrode 173 is formed of the semi-transmissive conductive material, light emission efficiency may be increased by a micro cavity.

The thin film encapsulation layer TFEL may be located on the second light emitting electrode 173. The thin film encapsulation layer TFEL may include at least one inorganic film to prevent or reduce instances of contaminants such as oxygen or moisture permeating into the light emitting element layer. In addition, the thin film encapsulation layer TFEL may include at least one organic film to protect the light emitting element layer from foreign substances such as dust. For example, the thin film encapsulation layer TFEL may include a first encapsulation film TFE1, a second encapsulation film TFE2, and a third encapsulation film TFE3.

The first encapsulation film TFE1 (e.g., a first inorganic encapsulation film) may be located on the second light emitting electrode 173. The first encapsulation film TFE1 may be an inorganic film of a single layer or a multi-layer. The first encapsulation film TFE1 may be formed of a single film or a multi-film in which one or more inorganic films of a silicon nitride layer, a silicon oxynitride layer, a silicon oxide layer, a titanium oxide layer, and an aluminum oxide layer are alternately stacked.

The second encapsulation film TFE2 (e.g., a first organic encapsulation film) may be located on the first encapsulation film TFE1. The second encapsulation film TFE2 may be an organic film of a single layer or a multi-layer. The second encapsulation film TFE2 may include a polymer-based material. Examples of the polymer-based material may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.), or any combination thereof.

The third encapsulation film TFE3 (e.g., a second inorganic encapsulation film) may be located on the second encapsulation film TFE2. The third encapsulation film TFE3 may be an inorganic film of a single layer or a multi-layer. The third encapsulation film TFE3 may include the same material as the first encapsulation film TFE1. For example, the third encapsulation film TFE3 may be formed of a single film or a multi-film in which one or more inorganic films of a silicon nitride layer, a silicon oxynitride layer, a silicon oxide layer, a titanium oxide layer, and an aluminum oxide layer are alternately stacked.

The touch sensor layer TSU may be located on the thin film encapsulation layer TFEL. The touch sensor layer TSU may include a plurality of touch electrodes for sensing a user's touch in a capacitance method, and touch lines connecting the plurality of touch electrodes and the touch driver. For example, the touch sensor layer TSU may sense the user's touch in a mutual capacitance method or a self-capacitance method.

According to some embodiments, the touch sensor layer TSU may be located on a separate substrate located on the display layer DU. In this case, the substrate supporting the touch sensor layer TSU may be an encapsulation member that encapsulates the display layer DU.

The plurality of touch electrodes of the touch sensor layer TSU may be located in a touch sensor area overlapping the display area. The touch lines of the touch sensor layer TSU may be located in a touch peripheral area overlapping the non-display area.

The touch sensor layer TSU may include a first touch insulating film SIL1, a first touch electrode REL, a second touch insulating film SIL2, a second touch electrode TEL, and a third touch insulating film SIL3.

The first touch insulating film SIL1 may be located on the thin film encapsulation layer TFEL. The first touch insulating film SIL1 may have insulation and optical functions. The first touch insulating film SIL1 may include at least one inorganic film. For example, the first touch insulating film SIL1 may be an inorganic film including at least one of a silicon nitride layer, a silicon oxynitride layer, a silicon oxide layer, a titanium oxide layer, or an aluminum oxide layer. Optionally, the first touch insulating film SIL1 may be omitted.

The first touch electrode REL may be located on the first touch insulating film SIL1. The first touch electrode REL may not overlap the light emitting element 170. The first touch electrode REL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second touch insulating film SIL2 may cover the first touch electrode REL and the first touch insulating film SIL1. The second touch insulating film SIL2 may have insulation and optical functions. For example, the second touch insulating film SIL2 may be made of the materials illustrated in the first touch insulating film SIL1.

The second touch electrode TEL may be located on the second touch insulating film SIL2. The second touch electrode TEL may not overlap the light emitting element 170. The second touch electrode TEL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The third touch insulating film SIL3 may cover the second touch electrode TEL and the second touch insulating film SIL2. The third touch insulating film SIL3 may have insulation and optical functions. The third touch insulating film SIL3 may be made of the materials illustrated in the second touch insulating film SIL2.

In some embodiments, the first touch insulating film SIL1, the second touch insulating film SIL2, and the third touch insulating film SIL3 may be organic films. For example, the first touch insulating film SIL1, the second touch insulating film SIL2, and the third touch insulating film SIL3 may be organic films made of an acryl resin, an epoxy resin, a phenolic resin, a polyamide resin, a polyimide resin, or the like.

The touch sensor layer TSU may further include a planarization film PAS for planarization. The planarization film PAS may be formed of an organic film made of an acrylic resin, an epoxy resin, a phenolic resin, a polyamide resin, a polyimide resin, or the like.

FIG. 6 is a cross-sectional view illustrating a viewing angle limited mode state of a display panel according to some embodiments. FIG. 7 is a cross-sectional view showing a wide viewing angle mode state of a display panel according to some embodiments.

Referring to FIGS. 6 and 7 in addition to FIGS. 1 to 3, the display area DA of the display device 10 may include a plurality of light emitting areas EA. The light emitting area EA may be an area where light emitted by the light emitting element 170 emits. The light emitting area EA may be defined by the bank 190. For example, the plurality of light emitting areas EA may be areas that overlap the light emitting layer 172 located within the opening of the bank 190. The light emitting area EA may be an area where the first light emitting electrode 171, the light emitting layer 172, and the second light emitting electrode 173 are sequentially stacked while overlapping each other.

In some embodiments, the plurality of light emitting areas EA may include a first light emitting area EA1, a second light emitting area EA2, and a third light emitting area EA3. It is illustrated in the drawing that three types of light emitting areas EA are included in the display area DA, but the present disclosure is not limited thereto and more or less than three types of light emitting areas EA may be included in the display area DA.

The first light emitting area EA1 may emit light of a first color, the second light emitting area EA2 may emit light of a second color, and the third light emitting area EA3 may emit light of a third color. The light of the first color may be light in a red wavelength band, the light of the second color may be light in a green wavelength band, and the light of the third color may be light in a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but the present disclosure is not limited thereto.

The light emitting areas EA of the display area DA may overlap the transmissive area OA and the non-transmissive area LSA in the third direction DR3. For example, the first to third light emitting areas EA1, EA2, and EA3 may overlap the transmissive area OA and the non-transmissive area LSA in the third direction DR3.

The transmissive area OA may be an area where the light blocking film LS of the light control layer LCL is not located. The non-transmissive area LSA may be an area where the light blocking film LS of the light control layer LCL is located.

The display panel 100 may include a display module 101 and a light control module 102. Because the display module 101 has been described with reference to FIG. 5, the description thereof will be omitted. The light control module 102 may be located on the display layer DU or the touch sensor layer TSU. The light control module 102 may include a light control layer LCL.

The light control layer LCL may control a viewing angle of light emitted from the light emitting layer 172. For example, when light emitted from the light emitting layer 172 travels at an angle (e.g., a set or predetermined angle) or less with respect to the third direction DR3, the light may be emitted to the outside. On the other hand, when the light emitted from the light emitting layer 172 travels beyond an angle (e.g., a set or predetermined angle) with respect to the third direction DR3, the light may be absorbed or blocked by the light blocking film LS and not emitted to the outside.

The light control layer LCL may be a viewing angle adjustment switching control structure capable of switching between a viewing angle limited mode and a wide viewing angle mode by the movement of electrophoretic particles that move depending on whether a voltage is applied.

The light control layer LCL may include a first light control electrode LE1, a light transmitting film LT, a light blocking film LS, an adhesive layer ADH, a second light control electrode LE2, and a second base substrate BS2.

The first light control electrode LE1 may be located on the display module 101. In some embodiments, the first light control electrode LE1 may be entirely arranged on an upper surface of the display module 101. For example, the first light control electrode LE1 may be located as a surface-type electrode on the upper surface of the display module 101. However, the first light control electrode LE1 is not limited thereto, and may be formed as a plurality of pattern electrodes having a certain pattern such as a mesh or stripe shape.

The first light control electrode LE1 may include a transparent conductive material. For example, the first light control electrode LE1 may include metal oxides such as indium tin oxide, indium zinc oxide, copper oxide, tin oxide, zinc oxide, and titanium oxide.

The first light control electrode LE1 may include a metal material to increase conductivity. For example, the first light control electrode LE1 may include at least one metal of chromium (Cr), nickel (Ni), copper (Cu), aluminum (Al), silver (Ag), molybdenum (Mo), gold (Au), titanium (Ti), and an alloy thereof.

The light transmitting film LT may transmit the light emitted from the light emitting layer 172. The light transmitting film LT may include a transparent organic material. For example, the light transmitting film LT may include an organic film made of an acryl resin, an epoxy resin, a phenolic resin, a polyamide resin, a polyimide resin, or the like.

The light transmitting film LT may be located on the first light control electrode LE1. The light transmitting film LT may be located in the transmissive area OA and the non-transmissive area LSA. For example, the light transmitting film LT may include a first portion located between the light blocking films LS, and a second portion located below the first portion.

The first portion of the light transmitting film LT may be arranged to alternate with the light blocking films LS in a horizontal direction intersecting the third direction DR3. The first portion of the light transmitting film LT may be located in the transmissive area OA. The second portion of the light transmitting film LT may be located on an entire surface of an upper surface of the first light control electrode LE1. The second portion of the light transmitting film LT may be arranged across the transmissive area OA and the non-transmissive area LSA.

In some embodiments, the light transmitting film LT may include a plurality of receiving portions located in the non-transmissive area LSA. The light blocking films LS may be located within the receiving portions of the light transmitting film LT. The receiving portions of the light transmitting film LT may be grooves recessed from an upper surface to a lower surface of the light transmitting film LT.

The light blocking film LS may absorb or block the light emitted from the light emitting layer 172. The light blocking film LS may include a light blocking organic material. For example, the light blocking film LS may include an organic material including an organic black pigment such as carbon black, as a photosensitive resin capable of absorbing or blocking light. The light blocking film LS may be located within the receiving portion of the light transmitting film LT.

A width W1 of the light blocking film LS may be approximately 5 μm to 20 μm. A distance D1 between the light blocking films LS may be approximately 20 μm to 60 μm. A thickness TH1 of the light blocking film LS may be approximately 150 μm or less. Preferably, the thickness TH1 of the light blocking film LS may be approximately 60 μm to 80 μm.

Like the first base substrate BS1, the second base substrate BS2 may include a first substrate SUB1, a first buffer film BF1, and a second substrate SUB2. However, the second base substrate BS2 is not limited thereto, and may also include only the first substrate SUB1. In some embodiments, a light transmittance of the second base substrate BS2 may be higher than that of the first base substrate BS1, but is not limited thereto.

The second light control electrode LE2 may be located on one surface of the second base substrate BS2. For example, as illustrated in the drawing, the second light control electrode LE2 may be located on a lower surface of the second base substrate BS2. The second light control electrode LE2 may be arranged to face the first light control electrode LE1 between the first base substrate BS1 and the second base substrate BS2.

In some embodiments, the second light control electrode LE2 may be entirely located on the lower surface of the second base substrate BS2. For example, the second light control electrode LE2 may be located a surface-type electrode on the lower surface of the second base substrate BS2. However, the second light control electrode LE2 is not limited thereto, and may be formed as a plurality of pattern electrodes having a certain pattern such as a mesh or stripe shape.

The second light control electrode LE2 may include a transparent conductive material. For example, the second light control electrode LE2 may include metal oxides such as indium tin oxide, indium zinc oxide, copper oxide, tin oxide, zinc oxide, and titanium oxide.

The second light control electrode LE2 may include a metal material to increase conductivity. For example, the second light control electrode LE2 may include at least one metal of chromium (Cr), nickel (Ni), copper (Cu), aluminum (Al), silver (Ag), molybdenum (Mo), gold (Au), titanium (Ti), and an alloy thereof.

In some embodiments, the second light control electrode LE2 may include the same material as the first light control electrode LE1, but is not limited thereto.

The adhesive layer ADH may be located on the second light control electrode LE2. For example, as illustrated in the drawing, the adhesive layer ADH may be located on a lower surface of the second light control electrode LE2. The adhesive layer ADH may be located on the light transmitting film LT and the light blocking film LS. The adhesive layer ADH may be located between the light transmitting film LT and the light blocking film LS, and the second light control electrode LE2 in the third direction DR3. The adhesive layer ADH may attach the second base substrate BS2 on which the second light control electrode LE2 is mounted on the first light control electrode LE1, the light transmitting film LT, and the light blocking film LS. In some embodiments, the adhesive layer ADH may be omitted.

In the display device 10 according to some embodiments, the light control layer LCL may be a viewing angle adjustment switching control structure capable of switching between a viewing angle limited mode and a wide viewing angle mode by the movement of electrophoretic particles that move depending on whether a voltage is applied.

For example, the light blocking film LS may include an ink solvent EPR and ink particles EPI.

The ink particles EPI may be electrophoretic particles. For example, the ink particles EPI may include carbon black nano-particles. As illustrated in FIG. 6, when light LGT generated from the light emitting layer 172 is incident on the ink particles EPI, the light LGT may be absorbed or blocked by the ink particles EPI and may not be emitted to the outside.

In some embodiments, the ink particles EPI may have a charge. For example, the ink particles EPI may have a positive or negative charge. Hereinafter, a case where the ink particles EPI have a negative charge will be described as an example.

The ink solvent EPR may be a substance that dissolves the ink particles EPI. For example, the ink solvent EPR may be, but is not limited to, paraffin oil. The ink solvent EPR may include a transparent material, and may transmit the light LGT generated from the light emitting layer 172.

In some embodiments, the ink solvent EPR may further include a charge control agent (CCA). By including the charge control agent, the ink solvent EPR may achieve a charge memory (or charge retention) effect of the ink particles EPI and achieve charge dispersion and stabilization of the ink particles EPI.

As illustrated in FIG. 7, in the wide viewing angle mode, a voltage may be applied to the first light control electrode LE1 and the second light control electrode LE2, respectively, and the first light control electrode LE1 and the second light control electrode LE2 may have different charges. As an example, the first light control electrode LE1 may have a positive charge, and the second light control electrode LE2 may have a negative charge. Accordingly, an electric field may be formed between the first light control electrode LE1 and the second light control electrode LE2. The ink particles EPI having the negative charge may move toward the first light control electrode LE1 having the positive charge. Therefore, in the wide viewing angle mode, because the ink particles EPI are aggregated to a lower portion of the light blocking film LS, most of the light LGT generated from the light emitting layer 172 may be emitted to the outside.

As another example, the first light control electrode LE1 may have a negative charge, and the second light control electrode LE2 may have a positive charge. Accordingly, the ink particles EPI having the negative charge may move toward the second light control electrode LE2 having the positive charge. Therefore, in the wide viewing angle mode, because the ink particles EPI are aggregated to an upper portion of the light blocking film LS, most of the light LGT generated from the light emitting layer 172 may be emitted to the outside.

Even when the ink particles EPI have a positive charge, the ink particles EPI may be aggregated toward an electrode having a negative charge among the first light control electrode LE1 and the second light control electrode LE2.

As illustrated in FIG. 6, in the viewing angle limited mode, because a voltage is not applied to the first light control electrode LE1 and the second light control electrode LE2, the first light control electrode LE1 and the second light control electrode LE2 may not have charges. Accordingly, the ink particles EPI having a negative charge may be dispersed within the light blocking film LS by repulsive force. Therefore, in the viewing angle limited mode, because the ink particles EPI are dispersed within the light blocking film LS, the light LGT generated from the light emitting layer 172 may be emitted to the outside only at a certain angle or less.

Hereinafter, aspects of a method for manufacturing a display device according to some embodiments will be described.

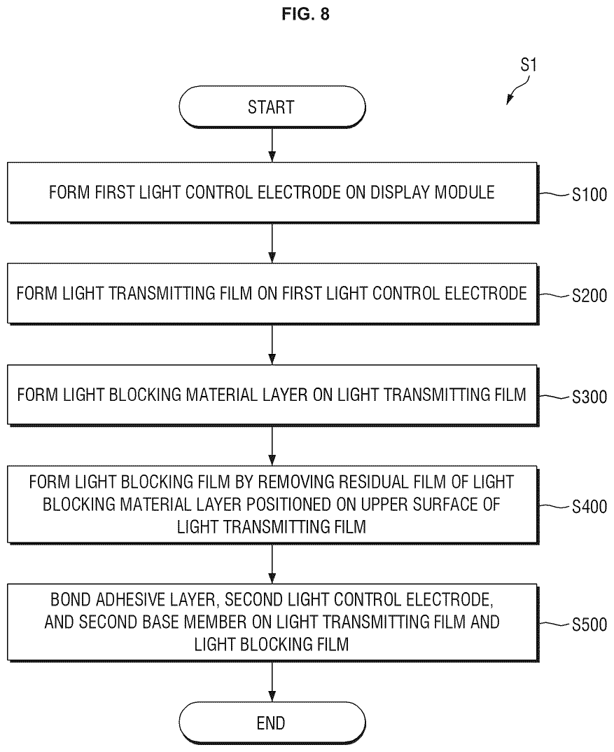

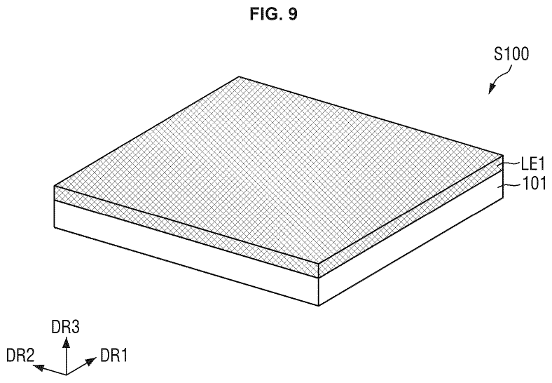

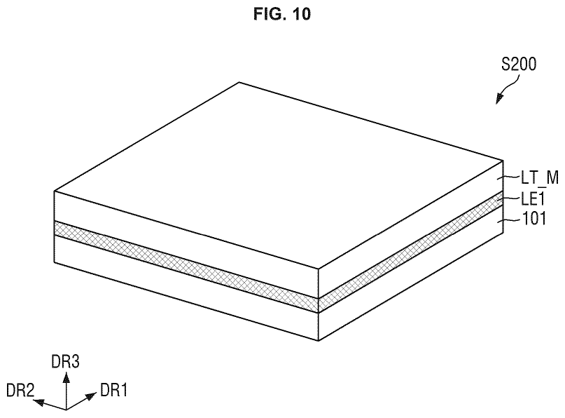

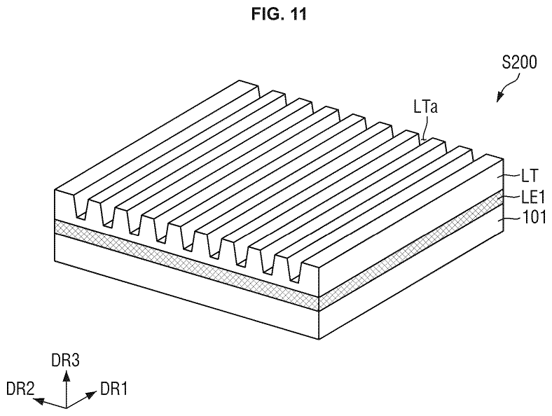

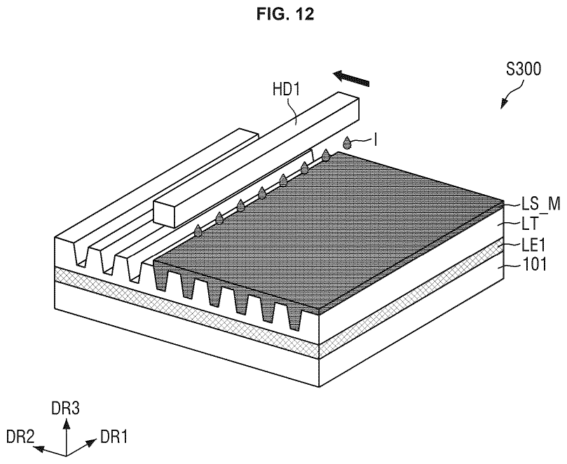

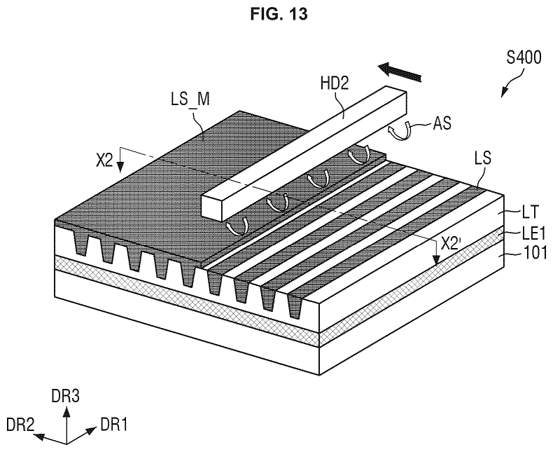

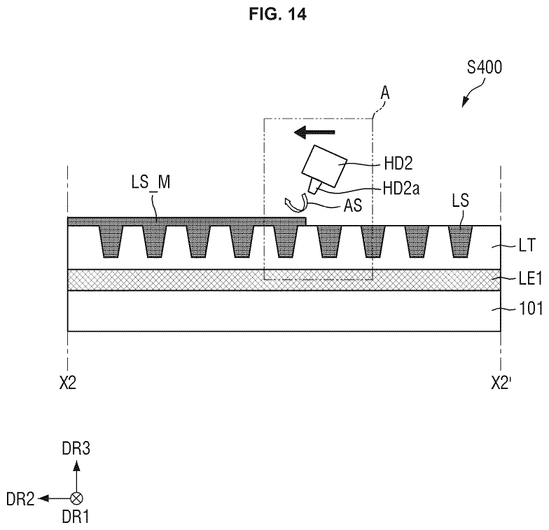

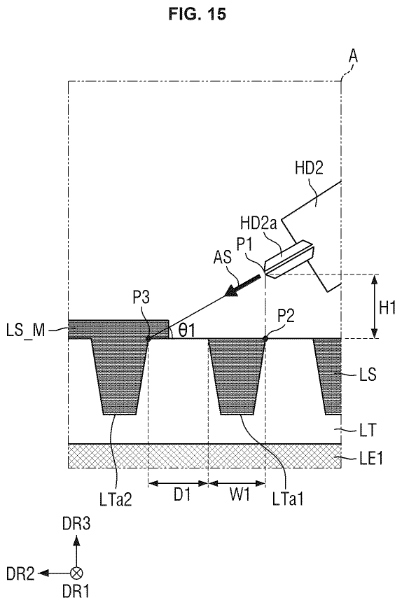

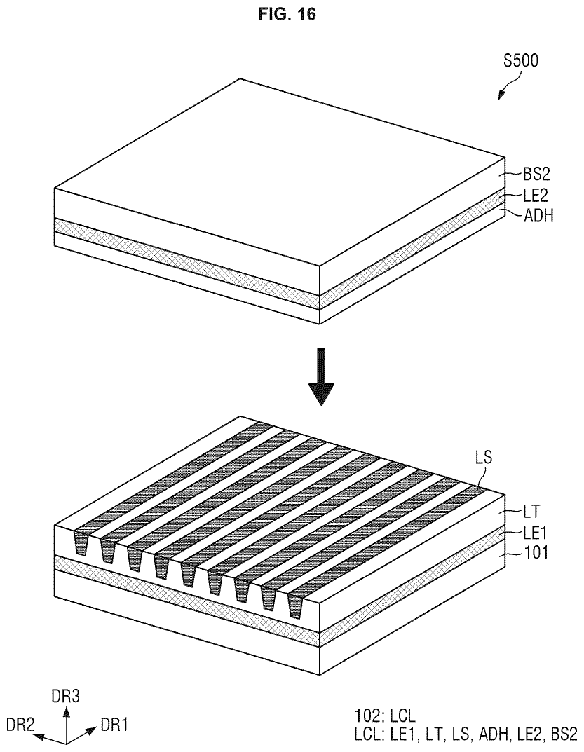

FIG. 8 is a flowchart illustrating a method for manufacturing a display device according to some embodiments. FIG. 9 is a perspective view illustrating operation S100 of FIG. 8. FIGS. 10 and 11 are perspective views illustrating operation S200 of FIG. 8. FIG. 12 is a perspective view illustrating operation S300 of FIG. 8. FIG. 13 is a perspective view illustrating operation S400 of FIG. 8. FIG. 14 is a cross-sectional view taken along line X2-X2′ of FIG. 13. FIG. 15 is an enlarged view of area A of FIG. 14. FIG. 16 is a perspective view illustrating operation S500 of FIG. 8.

Referring to FIGS. 8 to 16, a method (S1) for manufacturing a display device according to some embodiments may include an operation (S100) of forming a first light control electrode on a display module, an operation (S200) of forming a light transmitting film on the first light control electrode, an operation (S300) of forming a light blocking material layer on the light transmitting film, an operation (S400) of forming a light blocking film by removing a residual film of the light blocking material layer, and an operation (S500) of bonding an adhesive layer, a second light control electrode, and a second base substrate on the light transmitting film and the light blocking film.

As illustrated in FIG. 9, in the operation (S100) of forming the first light control electrode on the display module, a first light control electrode LE1 may be formed on a display module 101.

The first light control electrode LE1 may be formed by a physical vapor deposition (PVD) method such as sputtering, but is not limited thereto.

As illustrated in FIGS. 10 and 11, in the operation (S200) of forming the light transmitting film on the first light control electrode, a light transmitting material layer LT_M may be formed on the first light control electrode LE1.

The light transmitting material layer LT_M may be formed by an inkjet printing process. For example, the light transmitting material layer LT_M may be formed by applying ink on the first light control electrode LE1 using an inkjet printing device. However, the light transmitting material layer LT_M is not limited thereto and may also be formed by a deposition process.

Next, a light transmitting film LT may be formed by patterning the light transmitting material layer LT_M. The light transmitting film LT may include a plurality of receiving portions LTa. The plurality of receiving portions LTa may be grooves recessed from an upper surface to a lower surface of the light transmitting film LT.

According to some embodiments, when the light transmitting material layer LT_M is formed by an inkjet printing process, the light transmitting film LT may be formed by a molding process. The light transmitting film LT may be formed by molding the light transmitting material layer LT_M using a mold including protrusions to match the shape of the receiving portions LTa.

According to some embodiments, when the light transmitting material layer LT_M is formed by a deposition process, the light transmitting film LT may be formed through a photolithography process. The light transmitting film LT may be formed by etching the light transmitting material layer LT_M positioned in the receiving portion LTa.

As illustrated in FIG. 12, in the operation (S300) of forming the light blocking material layer on the light transmitting film (S300), a light blocking material layer LS_M may be formed on the light transmitting film LT.

As illustrated in the drawing, the light blocking material layer LS_M may be formed by an inkjet printing process. However, the light blocking material layer LS_M is not limited thereto and may also be formed by a dispensing or screen printing process.

When forming the light blocking material layer LS_M, a first head HD1 may apply ink I on the light transmitting film LT. The Ink I may be applied within the receiving portion LTa of the light transmitting film LT. However, in some embodiments, residues of the ink I may also remain on an upper surface of the light transmitting film LT positioned between the receiving portions LTa of the light transmitting film LT. Accordingly, a residual film may be formed within the receiving portion LTa and on the upper surface of the light transmitting film LT.

In some embodiments, a plasma treatment process may be first performed before applying the ink I on the light transmitting film LT. The plasma treatment process may be a process of performing hydrophobic treatment on the upper surface of the light transmitting film LT. For example, the hydrophobic treatment may be performed on the upper surface of the light transmitting film LT by performing oxygen plasma treatment on the light transmitting film LT.

As illustrated in FIGS. 13 to 15, in the operation (S400) of forming the light blocking film by removing the residual film of the light blocking material layer, the residual film of the light blocking material layer LS_M positioned on the upper surface of the light transmitting film LT may be removed, and the light blocking film LS may be formed inside the receiving portion LTa of the light transmitting film LT.

First, a second head HD2 may generate an air stream AS. The second head HD2 may be an air knife. The second head HD2 may include an air nozzle HD2a that sprays the air stream AS. The second head HD2 may remove the residual film by spraying the air stream AS to the residual film of the light blocking material layer LS_M positioned on the light transmitting film LT. As the residual film that prevents or reduces the light generated from the display module 101 being emitted to the outside is removed, a luminance of the display device 10 may be relatively improved.

The second head HD2 may extend in the first direction DR1, which is a direction in which the light transmitting film LT extends. The second head HD2 may move in the second direction DR2, which is a direction different from the direction in which the light transmitting film LT extends. However, the present disclosure is not limited thereto, and an object including the light blocking material layer LS_M and the light transmitting film LT may be moved instead of the second head HD2.

As illustrated in FIG. 15, the second head HD2 may spray the air stream AS in a diagonal direction along opposite directions of the second direction DR2 and the third direction DR3 while moving in the second direction DR2.

The air stream AS may remove the residual film of the light blocking material layer LS_M positioned on the upper surface of the light transmitting film LT and the residual film of the light blocking material layer LS_M positioned on the receiving portion LTa while moving in the second direction DR2. In some embodiments, an airflow volume of the air stream AS may be approximately 100 CFM (cubic feet/minute; ft³/min) or more. Preferably, the air volume of the air stream AS may be approximately 300 CFM.

In the method S1 for manufacturing the display device according to some embodiments, a first angle θ1, which is an angle formed between an extension direction of the upper surface of the light transmitting film LT and the spraying direction of the air stream AS may be determined by a distance D1 between the light blocking films LS, a width W1 of the light blocking films LS, and a height H1 of the air nozzle HD2a of the second head HD2. The height H1 of the air nozzle HD2a may be a distance in the third direction DR3 from an end P1 of the air nozzle HD2a to the upper surface of the light transmitting film LT.

In some embodiments, when the end P1 of the air nozzle HD2a coincides with a right end P2 of the first receiving portion LTa1 in the third direction DR3, a point where an extension line in the spraying direction of the air stream AS meets the upper surface of the light transmitting film LT may be a right end P3 of the second receiving portion LTa2 adjacent to the first receiving portion LTa1. For example, the first angle θ1 may satisfy Equation 1 below.

$$θ 1 = {tan}^{- 1} \{ H 1 / ( W 1 + D 1 ) \} \qquad Equation 1$$

In some embodiments, the height H1 of the air nozzle HD2a may be approximately 10 μm to 15 μm. As described above, the distance D1 between the light blocking films LS may be approximately 20 μm to 60 μm, and the width W1 of the light blocking films LS may be approximately 5 μm to 20 μm. Accordingly, the first angle θ1 may be approximately 5 degrees to 30 degrees.

In the method S1 for manufacturing the display device according to some embodiments, the ink I used when forming the light blocking material layer LS_M may have a relatively high viscosity. Due to the high viscosity of the ink I, an air stream AS with a high air volume may be sprayed to remove the residual film of the light blocking material layer LS_M positioned on the light transmitting film LT.

Because the second head HD2 sprays the air stream AS at the first angle θ1, it is possible to prevent or reduce instances of the light blocking material layer LS_M positioned inside the receiving portion LTa being removed together with the residual film by the air stream AS with a high air volume.

It is illustrated in the drawing that operations S300 and S400 are performed in time series, but the present disclosure is not limited thereto. For example, operations S300 and S400 may be performed simultaneously. In this case, the first head HD1 may move ahead of the second head HD2 and apply the ink I, while the second head HD2 may move behind the second head HD2 and remove the residual film.

As illustrated in FIG. 16, in the operation (S500) of bonding the adhesive layer, the second light control electrode, and the second base substrate on the light transmitting film and the light blocking film, a second base substrate BS2 on which the second light control electrode LE2 and the adhesive layer ADH are mounted may be bonded to the light transmitting film LT and the light blocking film LS.

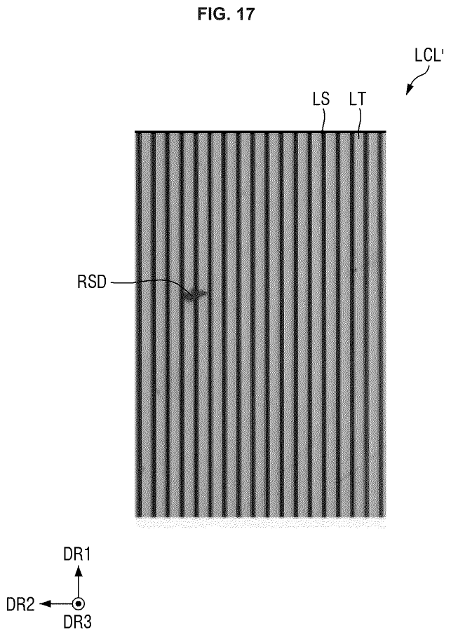

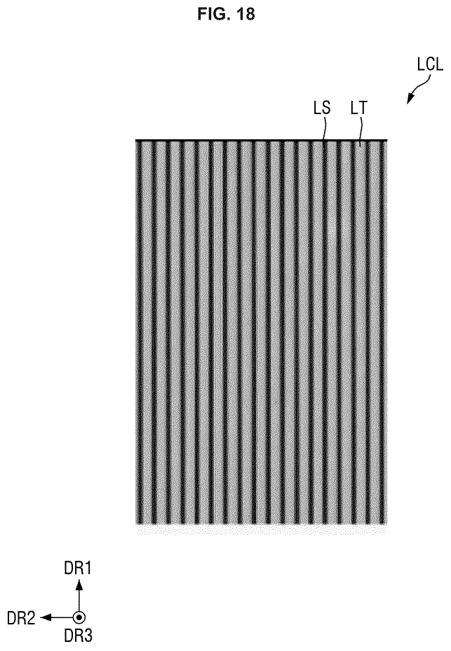

FIG. 17 is a photograph illustrating an upper surface of a light transmitting film and a light blocking film according to a comparative example. FIG. 18 is a photograph illustrating an upper surface of a light transmitting film and a light blocking film according to some embodiments.

Referring to FIGS. 17 and 18 in addition to FIGS. 8 to 16, an air knife process was not performed on a light control layer LCL′ according to the comparative example, and an air knife process was performed on the light control layer LCL according to some embodiments.

As illustrated in FIG. 17, in the light control layer LCL′ according to the comparative example, a residue RSD may remain on the light transmitting film LT. On the other hand, as illustrated in FIG. 18, in the light control layer LCL according to some embodiments, no residue RSD remains and may be completely removed.

Hereinafter, other embodiments of the method for manufacturing a display device according to some embodiments will be described. In the following embodiments, the same components as those of the above-described embodiments will be denoted by the same reference numerals, and some overlapping description thereof may be omitted or simplified and differences will be mainly described.

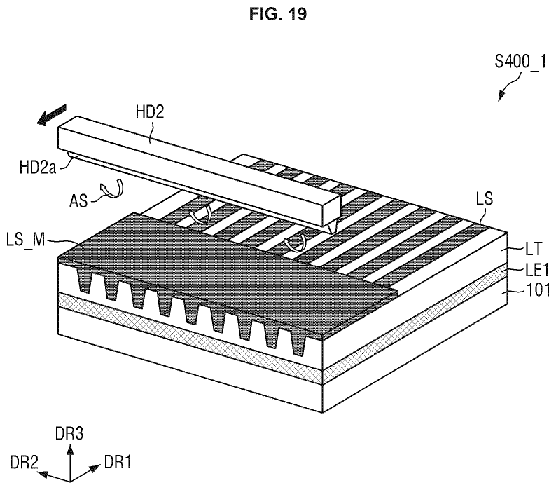

FIG. 19 is a perspective view illustrating operation S400_1 as another example of operation S400 of FIG. 8.

Referring to FIG. 19, a method S1 for manufacturing a display device according to the present embodiments is different from the method S1 for manufacturing the display device according to the embodiments described with reference to FIG. 8 and the like in that the moving direction of the second head HD2 is different.

More specifically, in the operation (S400_1) of forming a light blocking film by removing the residual film of the light blocking material layer of the method S1 for manufacturing the display device according to some embodiments, the second head HD2 may extend in the second direction DR2, which is a different direction from the direction in which the light transmitting film LT extends. The air nozzle HD2a of the second head HD2 may also extend in the second direction DR2. The second head HD2 may move in the first direction DR1, which is the direction in which the light transmitting film LT extends.

The second head HD2 may spray the air stream AS in a diagonal direction along the opposite direction of the first direction DR1 and the opposite direction of the third direction DR3 while moving in the first direction DR1.

The air stream AS may remove the residual film of the light blocking material layer LS_M positioned on the upper surface of the light transmitting film LT and the residual film of the light blocking material layer LS_M positioned on the receiving portion LTa while moving in the first direction DR1.

Because the moving direction of the air stream AS is the same as the direction in which the light transmitting film LT extends, it is possible to prevent or reduce instances of the light blocking material layer LS_M positioned inside the receiving portion LTa being removed together with the residual film by the air stream AS.

For example, the residual film positioned on the upper surface of the light transmitting film LT may move into the receiving portion LTa by the air stream AS. Because the air volume of the air stream AS is distributed in the second direction DR2, a force that the light blocking material layer LS_M positioned inside each of the receiving portions LTa receives from the air stream AS is distributed, so that instances of the light blocking material layer LS_M positioned inside the receiving portion LTa being removed together with the residual film by the air stream AS can be prevented or reduced.

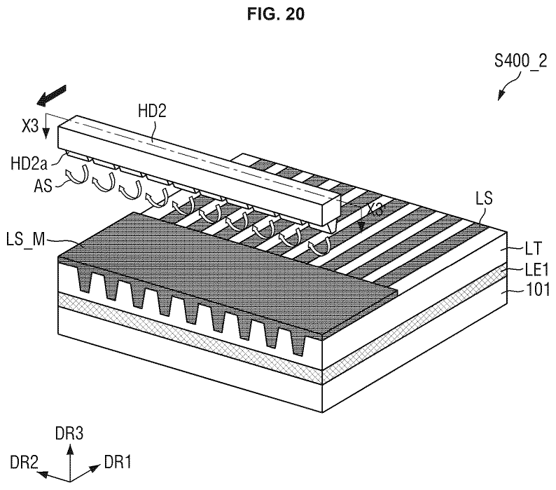

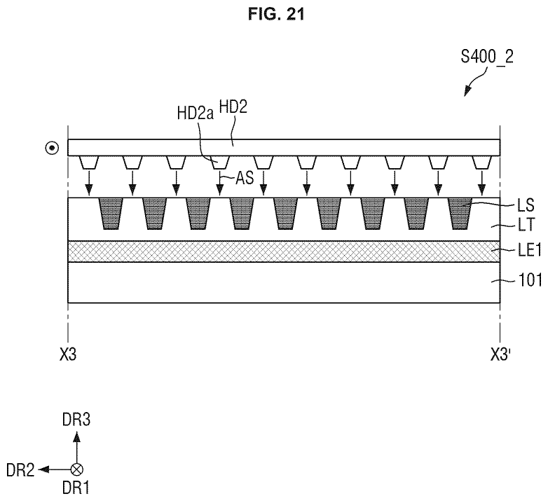

FIG. 20 is a perspective view illustrating operation S400_2 as still another example of operation S400 of FIG. 8. FIG. 21 is a cross-sectional view taken along line X3-X3′ of FIG. 20.

Referring to FIGS. 20 and 21, a method S1 for manufacturing a display device according to the present embodiments is different from the method S1 for manufacturing the display device described above with reference to FIG. 8 and the like in that the moving direction of the second head HD2 is different, and is different from the method S1 for manufacturing the display device according to embodiments described above with referent to FIG. 19 and the like in that the number of air nozzles HD2a is different.

More specifically, in the operation (S400_2) of forming a light blocking film by removing the residual film of the light blocking material layer of the method S1 for manufacturing the display device according to some embodiments, the second head HD2 may extend in the second direction DR2, which is a different direction from the direction in which the light transmitting film LT extends. The second head HD2 may move in the first direction DR1, which is the direction in which the light transmitting film LT extends.

The second head HD2 may include a plurality of air nozzles HD2a. The plurality of air nozzles HD2a may be arranged to be spaced apart from each other along the second direction DR2. The plurality of air nozzles HD2a may overlap portions other than the receiving portions LTa of the light transmitting film LT in the third direction DR3. The plurality of air nozzles HD2a may not overlap the receiving portions LTa of the light transmitting film LT in the third direction DR3. The plurality of air nozzles HD2a may be arranged alternately with the receiving portions LTa of the light transmitting film LT in the second direction DR2.

The plurality of air nozzles HD2a may spray the air stream AS to the portions other than the receiving portions LTa of the light transmitting film LT. Because the air stream AS sprayed by the plurality of air nozzles HD2a does not overlap the receiving portion LTa, it is possible to prevent the light blocking material layer LS_M positioned inside the receiving portion LTa from being removed together with the residual film by the air stream AS.

In concluding the detailed description, those skilled in the art will appreciate that many variations and modifications can be made to the disclosed embodiments without substantially departing from the spirit and scope of embodiments according to the present disclosure. Therefore, the disclosed embodiments of the invention are used in a generic and descriptive sense only and not for purposes of limitation.

What is claimed is:

1. A method for manufacturing a display device, the method comprising:
providing a first electrode on a display module, a light transmitting film on the first electrode, and a light blocking material layer on the light transmitting film;
forming a plurality of light blocking films by removing a residual film of the light blocking material layer on an upper surface of the light transmitting film; and
forming a second electrode on the light transmitting film and the plurality of light blocking films,
wherein the residual film is removed using an air knife.

2. The method of claim 1, wherein
the light transmitting film includes a plurality of receiving portions, and
the plurality of light blocking films are each within the plurality of receiving portions.

3. The method of claim 2, wherein the air knife sprays an air stream onto the light blocking material layer.

4. The method of claim 3, wherein
the plurality of receiving portions include a first receiving portion and a second receiving portion spaced apart from each other,
the air knife includes an air nozzle through which the air stream is sprayed, and
when an end of the air nozzle is on a right end of the first receiving portion, the air stream is sprayed toward a right end of the second receiving portion.

5. The method of claim 4, wherein
a first angle, which is an angle formed between an extension direction of the upper surface of the light transmitting film and a spraying direction of the air stream, is θ1,
a first distance, which is a distance between the plurality of light blocking films, is D1, and a first width, which is a width of the plurality of light blocking films, is W1,
a first height, which is a distance between the upper surface of the light transmitting film and the air nozzle, is H1, and
θ1=tan⁻¹{H1/(W1+D1)} is satisfied.

6. The method of claim 5, wherein the first angle is in a range of 5 degrees to 30 degrees.

7. The method of claim 6, wherein the first height is in a range of 10 μm to 15 μm.

8. The method of claim 6, wherein an air volume of the air stream is 100 CFM or more.

9. The method of claim 1, wherein the light blocking film includes electrophoretic particles.

10. The method of claim 9, wherein the electrophoretic particles have a charge.

11. The method of claim 9, wherein the light blocking film includes a charge control agent.

12. The method of claim 1, wherein the first electrode and the second electrode include a transparent conductive material.

13. A method for manufacturing a display device, the method comprising:
providing a first electrode on a display module, a light transmitting film on the first electrode, and an object including a light blocking material layer on the light transmitting film;
forming a plurality of light blocking films by removing a residual film of the light blocking material layer on an upper surface of the light transmitting film; and
forming a second electrode on the light transmitting film and the plurality of light blocking films, wherein
the light transmitting film includes a plurality of receiving portions extending in a first direction and in a second direction different from the first direction, and
the residual film is removed using an air knife.

14. The method of claim 13, wherein at least one of the air knife or the object moves in the second direction.

15. The method of claim 14, wherein
the plurality of receiving portions include a first receiving portion and a second receiving portion spaced apart from each other,
the air knife includes an air nozzle through which an air stream is sprayed, and
when an end of the air nozzle is positioned on a right end of the first receiving portion, the air stream is sprayed toward a right end of the second receiving portion.

16. The method of claim 15, wherein
a first angle, which is an angle formed between an extension direction of the upper surface of the light transmitting film and a spraying direction of the air stream, is θ1,
a first distance, which is a distance between the plurality of light blocking films, is D1, and a first width, which is a width of the plurality of light blocking films, is W1,
a first height, which is a distance between the upper surface of the light transmitting film and the air nozzle, is H1, and
θ1=tan⁻¹{H1/(W1+D1)} is satisfied.

17. The method of claim 13, wherein at least one of the air knife or the object moves in the first direction.

18. The method of claim 17, wherein the air knife includes an air nozzle through which an air stream is sprayed.

19. The method of claim 18, wherein the air nozzle extends in the second direction, and overlaps the plurality of receiving portions.

20. The method of claim 18, wherein
the air nozzle includes a plurality of air nozzles, and
the plurality of air nozzles each overlap portions of the light transmitting film other than the plurality of receiving portions.
